(19) United States
(12) Patent Application Publication
(10) Pub. No.: US 2021/0111218 A1
(43) Pub. Date: Apr. 15, 2021

(54) IMAGING PANEL AND METHOD FOR MANUFACTURING SAME

(71) Applicant: Sharp Kabushiki Kaisha, Sakai City, Osaka (JP)

(72) Inventors: Yu NAKAMURA, Sakai City (JP); Kazuhide TOMIYASU, Sakai City (JP); Makoto NAKAZAWA, Sakai City (JP); Hiroyuki MORIWAKI, Sakai City (JP); Wataru NAKAMURA, Sakai City (JP); Fumiki NAKANO, Sakai City (JP)

(21) Appl. No.: 16/498,499

(22) PCT Filed: Mar. 28, 2018
(86) PCT No.: PCT/JP2018/012669

§ 371 Date: Sep. 27, 2019

(30) Foreign Application Priority Data
Mar. 30, 2017 (JP) 2017-068933

(51) Int. Cl. H01L 27/146; G01T 1/20

(52) U.S. Cl. CPC H01L 27/14663; G01T 1/2018; H01L 27/14689

(57) ABSTRACT

Provided are an X-ray imaging panel capable of suppressing a leak current of a photoelectric conversion layer while reducing the number of steps for manufacturing the imaging panel, and a method for manufacturing the same. An imaging panel 1 generates an image based on scintillation light obtained from X-rays passing through a subject. The imaging panel 1 is provided with a thin film transistor 13, passivation films 103 and 104 covering the thin film transistor 13, a photoelectric conversion layer 15 converting scintillation light into a charge, an upper electrode 16, and a lower electrode 14 connected to the thin film transistor 13, on a substrate 101. End portions of the lower electrode 14 are disposed on an inner side than the end portions of the photoelectric conversion layer 15. The lower electrode 14 and the thin film transistor 13 are connected to each other via a contact hole CH1 formed in the passivation films 103 and 104, in a region in which the photoelectric conversion layer 15 is provided.

### TECHNICAL FIELD

The present invention relates to an imaging panel and a method for manufacturing the same.

### BACKGROUND ART

An X-ray imaging device that photographs an X-ray image by an imaging panel provided with a plurality of pixel parts is known. In such X-ray imaging device, for example, emitted X-rays are converted into charges by a p-intrinsic-n (PIN) photodiode including a photoelectric conversion layer and upper and lower electrodes provided above and below the photoelectric conversion layer. The converted charges are read out by operating a thin film transistor (hereinafter, also referred to as ‘TFT’) provided in the pixel part. By the charges read out in this way, an X-ray image is obtained (refer to Japanese Unexamined Patent Application Publication No. 2014-78651).

### DISCLOSURE OF INVENTION

In Japanese Unexamined Patent Application Publication No. 2014-78651, it is disclosed that the lower electrode and the thin film transistor in the PIN photodiode are connected to each other at a position on an outer side than end portions of the photoelectric conversion layer, and thus a passivation film is required between the photoelectric conversion layer and the thin film transistor. Further, in a case where end portions of the lower electrode are disposed on an outer side than the end portions of the photoelectric conversion layer, when performing a reduction treatment using hydrogen fluoride on side surfaces of the photoelectric conversion layer, the lower electrode is exposed to hydrogen fluoride if the end portions of the lower electrode are not covered with a protective film or the like. In this case, metal ions in which the lower electrode is dissolved may adhere to the photoelectric conversion layer.

An object of the present invention is to provide an X-ray imaging panel and a method for manufacturing the X-ray imaging panel capable of suppressing a leak current of a photoelectric conversion layer while reducing the number of steps for manufacturing an imaging panel.

An imaging panel of the present invention for solving the above-described problems is an imaging panel which generates an image based on scintillation light obtained from X-rays passing through an object, the imaging panel including a substrate; a thin film transistor formed on the substrate; a passivation film covering the thin film transistor; a lower electrode provided on the passivation film and connected to the thin film transistor; a photoelectric conversion layer provided on the passivation film and the lower electrode, and converting the scintillation light into a charge; and an upper electrode provided on the photoelectric conversion layer, in which end portions of the lower electrode are disposed on an inner side than end portions of the photoelectric conversion layer, and the lower electrode and the thin film transistor are connected to each other via a contact hole formed in the passivation film, in a region in which the photoelectric conversion layer is provided.

According to the present invention, it is possible to suppress a leak current of a photoelectric conversion layer while reducing the number of steps for manufacturing an imaging panel.

### BRIEF DESCRIPTION OF DRAWINGS

FIG. 1 is a schematic diagram illustrating an X-ray imaging device according to an embodiment.

FIG. 2 is a schematic diagram illustrating a schematic configuration of an imaging panel shown in FIG. 1.

FIG. 3 is a plan diagram obtained by enlarging a portion of one pixel the imaging panel 1 shown in FIG. 2.

FIG. 4A is a cross-sectional diagram taken along line A-A of the pixel shown in FIG. 3.

FIG. 4B is a cross-sectional diagram for explaining positions of end portions of a lower electrode, a photoelectric conversion layer, and an upper electrode shown in FIG. 4A.

FIG. 5A is a cross-sectional diagram illustrating a step of forming a gate insulating film and a TFT to form a first insulating film on a substrate.

FIG. 5B is a cross-sectional diagram illustrating a step of forming a second insulating film on the first insulating film shown in FIG. 5A.

FIG. 5C is a cross-sectional diagram illustrating a step of forming a contact hole penetrating through the first insulating film and the second insulating film shown in FIG. 5B.

FIG. 5D is a cross-sectional diagram illustrating a step of forming a metal film on the second insulating film in FIG. 5C.

FIG. 5E is a cross-sectional diagram illustrating a step of forming a lower electrode by patterning the metal film in FIG. 5D.

FIG. 5F is a cross-sectional diagram illustrating a step of forming an n-type amorphous semiconductor layer, an intrinsic amorphous semiconductor layer, and a p-type amorphous semiconductor layer, which cover the lower electrode shown in FIG. 5D, and forming a transparent conductive film on the p-type amorphous semiconductor layer.

FIG. 5G is a cross-sectional diagram illustrating a step of forming an upper electrode by patterning the transparent conductive film shown in FIG. 5F.

FIG. 5H is a cross-sectional diagram illustrating a step of forming an insulating film covering the upper electrode shown in FIG. 5G, and applying a resist on the insulating film.

FIG. 5I is a cross-sectional diagram illustrating a step of forming a photoelectric conversion layer and a protective film by patterning the insulating film, the n-type amorphous semiconductor layer, the intrinsic amorphous semiconductor layer, and the p-type amorphous semiconductor layer shown in FIG. 5H, and performing a reduction treatment using hydrogen fluoride.

FIG. 5J is a cross-sectional diagram illustrating a step of peeling off the resist shown in FIG. 5I, and forming a third insulating film covering the photoelectric conversion layer and the protective film.

FIG. 5K is a cross-sectional diagram illustrating a step of forming a contact hole penetrating through the third insulating film and the protective film shown in FIG. 5J.

FIG. 5L is a cross-sectional diagram illustrating a step of forming a fourth insulating film on the third insulating film shown in FIG. 5K and forming an opening of the fourth insulating film.

FIG. 5M is a cross-sectional diagram illustrating a step of forming a first bias wiring layer and a second bias wiring layer on the fourth insulating film shown in FIG. 5L.

FIG. 5N is a cross-sectional diagram illustrating a step of patterning the first bias wiring layer and the second bias wiring layer shown in FIG. 5M to form bias wiring.

FIG. 5O is a cross-sectional diagram illustrating a step of forming a fifth insulating film covering the bias wiring shown in FIG. 5N and forming a sixth insulating film on the fifth insulating film.

### DESCRIPTION OF EMBODIMENTS

An imaging panel according to an embodiment of the present invention is an imaging panel which generates an image based on scintillation light obtained from X-rays passing through an object, the panel including: a substrate; a thin film transistor formed on the substrate; a passivation film covering the thin film transistor; a lower electrode provided on the passivation film and connected to the thin film transistor; a photoelectric conversion layer provided on the passivation film and the lower electrode, which converts the scintillation light into a charge; and an upper electrode provided on the photoelectric conversion layer, in which end portions of the lower electrode are disposed on an inner side than end portions of the photoelectric conversion layer, and the lower electrode and the thin film transistor are connected to each other via a contact hole formed in the passivation film, in a region in which the photoelectric conversion layer is provided (first configuration).

In a case where the end portions of the lower electrode are disposed on an outer side than the end portions of the photoelectric conversion layer and the lower electrode and the thin film transistor are connected to each other at a position of an on an outer side than the end portions of the photoelectric conversion layer, passivation films are required between the thin film transistor and the lower electrode, and between the photoelectric conversion layer and the thin film transistor respectively. According to the first configuration, since one passivation film may be provided between the thin film transistor, and the lower electrode and the photoelectric conversion layer, as compared with the above-described case, the number of steps for manufacturing the imaging panel can be reduced. Further, since the end portions of the lower electrode are covered with the photoelectric conversion layer, even if a reduction treatment is performed using hydrogen fluoride on side surfaces of the photoelectric conversion layer, when the photoelectric conversion layer is formed, the lower electrode is not exposed to hydrogen fluoride and thus a leak current of the photoelectric conversion layer can be suppressed.

In the first configuration, the end portions of the upper electrode may be disposed on an inner side than the end portions of the lower electrode (second configuration).

According to the second configuration, the end portions of the upper electrode and the end portions of the lower electrode are disposed on an inner side than the end portions of the photoelectric conversion layer. Therefore, even if the photoelectric conversion layer is etched after the upper electrode is formed, metal ions of the upper electrode are less likely to adhere to the photoelectric conversion layer under an influence of the etching. Moreover, compared with the case where the end portions of the upper electrode are disposed on an outer side than the end portions of the lower electrode, the upper electrode and the photoelectric conversion layer can be surely brought into contact with each other.

In the first configuration, a protective film covering the upper electrode is further provided on the photoelectric conversion layer, and end portions of the protective film may be disposed on substantially the same position as the end portions of the photoelectric conversion layer (third configuration).

According to the third configuration, the upper electrode is covered with the protective film. Therefore, after the photoelectric conversion layer is formed, for example, even if a reduction treatment using hydrogen fluoride or the like is performed to suppress a leak current, the upper electrode is not affected by a reduction treatment, and thus the metal ions of the upper electrode are less likely to adhere to the photoelectric conversion layer.

A manufacturing method according to another embodiment of the present invention is a method for manufacturing an imaging panel which generates an image based on scintillation light obtained from X-rays passing through an object, the method including: a step of forming a thin film transistor on a substrate; a step of forming a passivation film on the thin film transistor; a step of forming a contact hole penetrating through the passivation film, on a drain electrode of the thin film transistor; a step of forming a lower electrode connected to the drain electrode via the contact hole, on the passivation film; a step of forming a first semiconductor layer having a first conductivity type, an intrinsic amorphous semiconductor layer, and a second semiconductor layer having a second conductivity type opposite to the first conductivity type in this order, on the passivation film and the lower electrode; a step of forming an upper electrode on the second semiconductor layer; and a step of forming a photoelectric conversion layer by etching the first semiconductor layer, the intrinsic amorphous semiconductor layer, and the second semiconductor layer, in which, in the step of the forming of the photoelectric conversion layer, the etching is performed such that end portions of the lower electrode are disposed on an inner side than end portions of the photoelectric conversion layer, and the contact hole is formed on an inner side than the end portions of the photoelectric conversion layer (fourth configuration).

According to the fourth configuration, the end portions of the lower electrode are disposed on an inner side than the end portions of the photoelectric conversion layer, and the thin film transistor and the lower electrode are connected to each other on an inner side than the end portions of the photoelectric conversion layer. In a case where the end portions of the lower electrode are disposed on an outer side than the end portions of the photoelectric conversion layer, and the thin film transistor and the lower electrode are connected to each other on an outer side than the end portions of the photoelectric conversion layer, passivation films are required between the thin film transistor and the lower electrode, and between the photoelectric conversion layer and the thin film transistor, respectively. In the present configuration, since one passivation film is provided between the thin film transistor, and the lower electrode and the photoelectric conversion layer, compared with the above-described case, the number of the steps for manufacturing the imaging panel can be reduced. Also, since the end portions of the lower electrode are covered with the photoelectric conversion layer, even if a reduction treatment using hydrogen fluoride is performed on side surfaces of the photoelectric conversion layer when the photoelectric conversion layer is formed, the lower electrode is not exposed to hydrogen fluoride, thereby a leak current of the photoelectric conversion layer can be suppressed.

In the fourth configuration, a step of performing a reduction treatment using hydrogen fluoride on a surface of the photoelectric conversion layer may be further included after the performing of the etching such that end portions of the upper electrode are disposed on an inner side than the end portions of the photoelectric conversion layer in the step of the forming of the photoelectric conversion layer (fifth configuration).

According to the fifth configuration, since the end portions of the photoelectric conversion layer are disposed on an outer side than the end portions of the upper electrode, the upper electrode is less likely to be exposed to hydrogen fluoride even if a reduction treatment is performed using hydrogen fluoride after the formation of the photoelectric conversion layer. Therefore, the metal ions of the upper electrode are less likely to adhere to the photoelectric conversion layer, and a leak current of the photoelectric conversion layer can be suppressed.

In the fourth or fifth configuration, a step of forming a protective film covering the upper electrode on the photoelectric conversion layer may be further included (sixth configuration).

According to the sixth configuration, since the upper electrode is covered with the protective film, the upper electrode is not exposed to hydrogen fluoride even if a reduction treatment is performed using hydrogen fluoride after formation of the photoelectric conversion layer, thereby a leak current of the photoelectric conversion layer can be suppressed.

Hereinafter, embodiments of the present invention are described in detail with reference to the drawings. The same or corresponding parts in the drawings have the same reference numerals and the description thereof will not be repeated.

### First Embodiment

(Configuration)

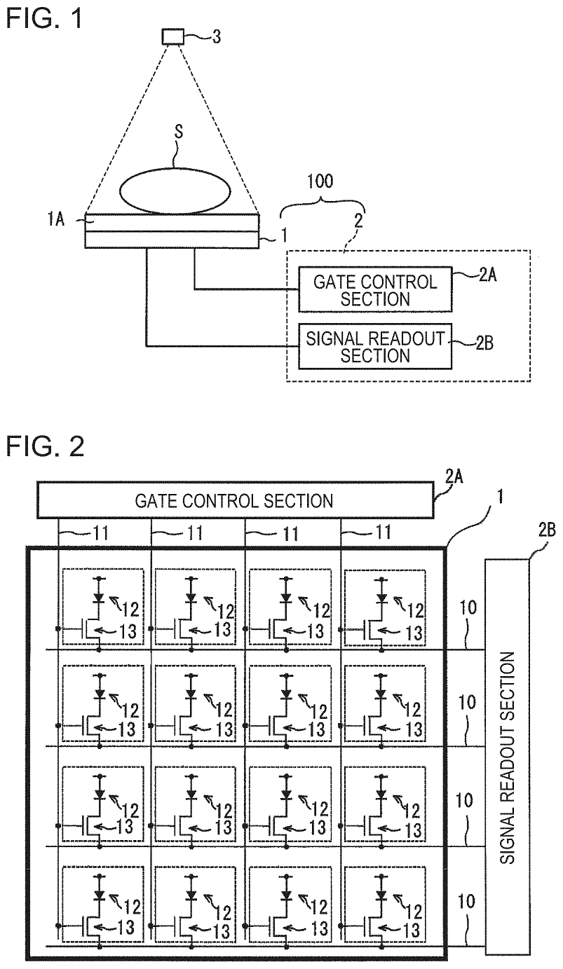

FIG. 1 is a schematic diagram illustrating an X-ray imaging device according to the present embodiment. An X-ray imaging device 100 is provided with an imaging panel 1 and a control unit 2. The control unit 2 includes a gate control section 2A and a signal readout section 2B. An object S is irradiated with X-rays from an X-ray source 3 and the X-rays transmitted through the object S are converted into fluorescence (hereinafter, referred to as scintillation light) by a scintillator 1A disposed on the imaging panel 1. The X-ray imaging device 100 captures an image of scintillation light by the imaging panel 1 and the control unit 2 to acquire an X-ray image.

FIG. 2 is a schematic diagram illustrating a schematic configuration of the imaging panel 1. As illustrated in FIG. 2, a plurality of source wirings 10 and a plurality of gate wirings 11 intersecting the plurality of source wirings 10 are formed in the imaging panel 1. The gate wirings 11 are connected to a gate control section 2A, and the source wirings 10 are connected to a signal readout section 2B.

The imaging panel 1 includes TFTs 13 which is connected to the source wirings 10 and the gate wirings 11 at a position where the source wirings 10 and the gate wirings 11 intersect. Further, a photodiode 12 is provided in a region (hereinafter, referred to as a pixel) surrounded by the source wiring 10 and the gate wiring 11. In the pixel, scintillation light obtained by converting the X-rays transmitted through the object S is converted into charges corresponding to the amount of light by the photodiode 12.

Each gate wiring 11 in the imaging panel 1 is sequentially switched to a selected state by the gate control section 2A, and the TFT 13 connected to the gate wiring 11 in the selected state is turned on. If the TFT 13 is turned on, a signal corresponding to the charge converted by the photodiode 12 is output to the signal readout section 2B through the source wiring 10.

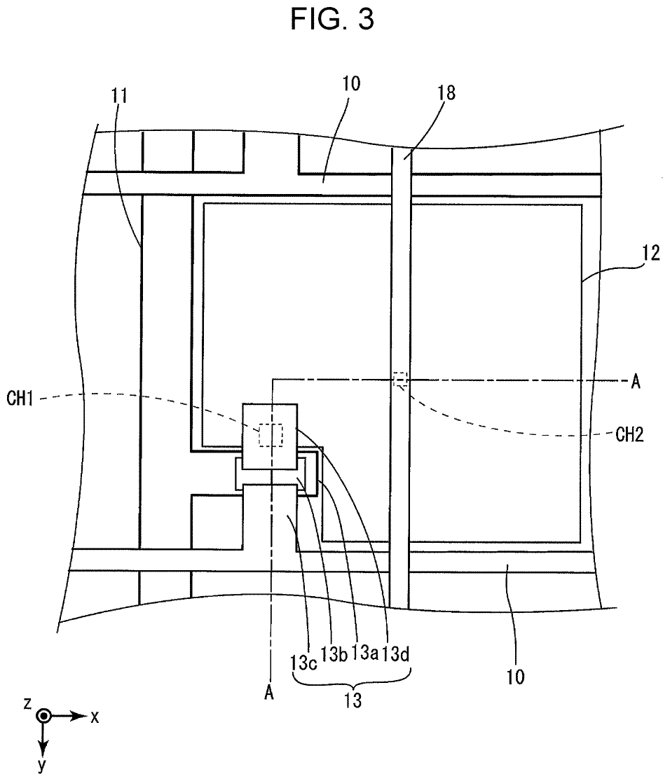

FIG. 3 is a plan diagram obtained by enlarging a portion of one pixel of the imaging panel 1 shown in FIG. 2. As illustrated in FIG. 3, the pixel surrounded by the gate wiring 11 and the source wiring 10 is provided with the photodiode 12 and the TFT 13. Further, bias wirings 18 are disposed so as to overlap with the photodiode 12 in a plan view.

The bias wirings 18 supply a bias voltage to the photodiode 12.

The TFT 13 includes a gate electrode 13a integrated with the gate wiring 11, a semiconductor active layer 13b, a source electrode 13c integrated with the source wiring 10, and a drain electrode 13d.

The photodiode 12 includes an upper electrode to be described later, a lower electrode, and a photoelectric conversion layer provided between the upper electrode and the lower electrode.

In the pixel, a contact hole CH1 for connecting the drain electrode 13d to the lower electrode of the photodiode 12 and a contact hole CH2 for connecting the bias wirings 18 to the photodiode 12 are provided.

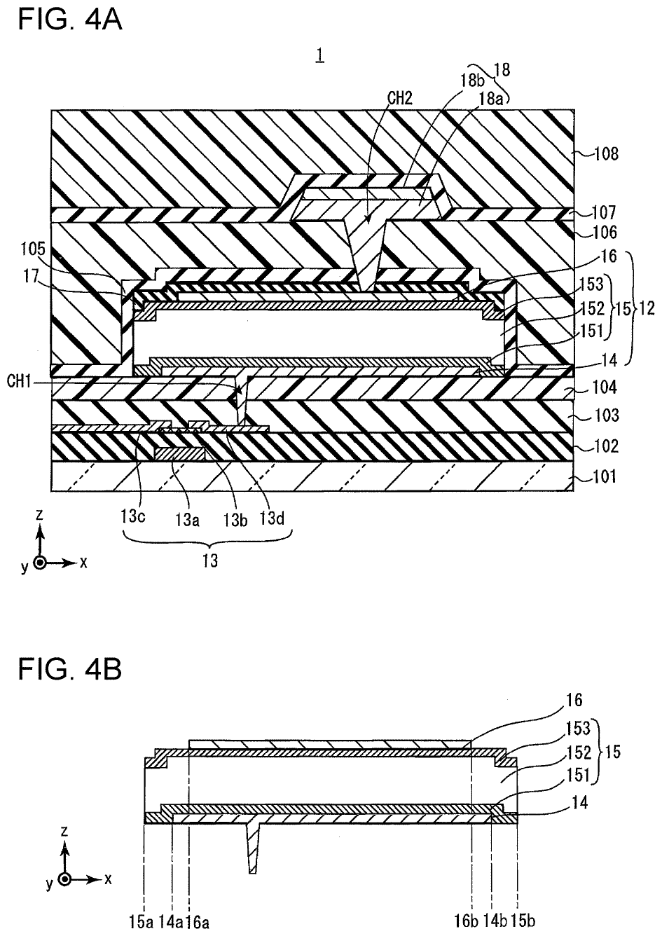

Here, FIG. 4A is a cross-sectional diagram taken along line A-A of the pixel shown in FIG. 3. As illustrated in FIG. 4A, the gate electrode 13a integrated with the gate wiring 11 is formed on a substrate 101.

The substrate 101 is, for example, an insulating substrate such as a glass substrate, a silicon substrate, a plastic substrate having heat-resistance, or a resin substrate.

The gate electrode 13a and the gate wiring 11 consist of, for example, metals such as aluminum (Al), tungsten (W), molybdenum (Mo), molybdenum nitride (MoN), tantalum (Ta), chromium (Cr), titanium (Ti), copper (Cu), or an alloy thereof, or a metal nitride thereof.

In the present embodiment, the gate electrode 13a and the gate wiring 11 have a stacked structure in which a metal film consisting of tungsten (W) is stacked on an upper layer and a metal film consisting of tantalum (Ta) is stacked on a lower layer. In this example, a thickness of the metal film consisting of tungsten (W) is about 300 nm and a thickness of the metal film consisting of tantalum (Ta) is about 30 nm.

The gate insulating film 102 is disposed on the substrate 101 so as to cover the gate electrode 13a. For the gate insulating film 102, for example, silicon oxide (SiOx), silicon nitride (SiNx), silicon oxynitride (SiOxNy) (x>y), silicon nitride oxide (SiNxOy) (x>y), or the like may be used. In the present embodiment, the gate insulating film 102 is configured by sequentially stacking silicon oxide (SiOx) and silicon nitride (SiNx). In this example, the film thickness of silicon oxide (SiOx) is about 300 nm, and the film thickness of silicon nitride (SiNx) is about 50 nm.

On the gate electrode 13a, the semiconductor active layer 13b, the source electrode 13c connected to the semiconductor active layer 13b, and the drain electrode 13d are disposed via the gate insulating film 102.

The semiconductor active layer 13b is formed in contact with the gate insulating film 102. The semiconductor active layer 13b is made of an oxide semiconductor. The oxide semiconductor may be, for example, an amorphous oxide semiconductor or the like containing InGaO₃ (ZnO)₅, magnesium zinc oxide (MgxZn₁-xO), cadmium zinc oxide (CdxZn₁-xO), cadmium oxide (CdO), or indium (In), gallium (Ga) and zinc (Zn) in a predetermined ratio. In the present embodiment, the semiconductor active layer 13b is made of an oxide semiconductor containing indium (In), gallium (Ga), and zinc (Zn) in a predetermined ratio, and the film thickness thereof is about 100 nm.

A leak current of the TFT 13 can be reduced by using an oxide semiconductor containing indium (In), gallium (Ga), and zinc (Zn) in a predetermined ratio as the semiconductor active layer 13b of the TFT 13. A leak current of the photoelectric conversion layer 15 to be described later also can be reduced by the reduction of the leak current of the TFT 13. As a result, a quantum efficiency of the photoelectric conversion layer 15 is improved, and detection sensitivity of X-rays in the X-ray imaging device 100 is improved.

The source electrode 13c and the drain electrode 13d are formed in contact with the semiconductor active layer 13b and the gate insulating film 102. The source electrode 13c is integrated with the source wiring 10.

The source electrode 13c and the drain electrode 13d are formed on the same layer, and consist of, for example, metals such as aluminum (Al), tungsten (W), molybdenum (Mo), tantalum (Ta), chromium (Cr), titanium (Ti), copper (Cu), or the like, or an alloy thereof, or a metal nitride thereof. Also, as materials of the source electrode 13c and the drain electrode 13d, materials having translucency such as indium tin oxide (ITO), indium zinc oxide (IZO), indium tin oxide containing silicon oxide (ITSO), indium oxide (In₂O₃), tin oxide (SnO₂), zinc oxide (ZnO), titanium nitride, or the like, and materials obtained by combining these suitably may be used. The source electrode 13c and the drain electrode 13d may be, for example, formed by stacking a plurality of metal films.

Specifically, the source electrode 13c, the source wiring 10, and the drain electrode 13d have the stacked structure in which a metal film consisting of molybdenum nitride (MoN), a metal film consisting of aluminum (Al), and a metal film consisting of molybdenum nitride (MoN) are stacked in this order. A film thickness of the metal film consisting of molybdenum nitride (MoN) of the upper layer and the lower layer is about 50 nm, and a film thickness of the metal film consisting of aluminum (Al) is about 300 nm.

The first insulating film 103 and the second insulating film 104 are stacked as a passivation film so as to cover the source electrode 13c and the drain electrode 13d. In the present embodiment, the first insulating film 103 is formed of, for example, silicon oxide (SiO₂), and the thickness thereof is about 300 nm. The second insulating film 104 is formed of, for example, silicon nitride (SiNx), and the thickness thereof is about 200 nm. Silicon oxide (SiO²) has a larger effect of preventing deterioration of TFT characteristics due to reduction of oxide semiconductors by hydrogen than silicon nitride (SiNx) having a large hydrogen content. Also, since silicon nitride (SiNx) has higher density than that of silicon oxide (SiO₂), water (H₂O) or other impurities is prevented from entering thereby the effect of improving the reliability of the TFT is great. Therefore, by stacking silicon oxide (SiO₂) and silicon nitride (SiNx), two effects of preventing deterioration of the TFT characteristics and improving the reliability of the TFT can be achieved.

In this example, the passivation film has a structure in which the first insulating film 103 and the second insulating film 104 are stacked, but may be configured with one insulating film.

On the drain electrode 13d, the contact hole CH1 penetrating through the second insulating film 104 and the first insulating film 103 is formed.

On the second insulating film 104, the lower electrode 14 connected to the drain electrode 13d is formed in the contact hole CH1. The lower electrode 14 has a stacked structure in which titanium (Ti), aluminum (Al), and titanium (Ti) are stacked. The film thicknesses of titanium (Ti) of the upper layer and the lower layer are about 50 nm, and the film thickness of aluminum (Al) is about 300 nm.

The photoelectric conversion layer 15 is formed on the lower electrode 14. The photoelectric conversion layer 15 is configured by stacking an n-type amorphous semiconductor layer 151, an intrinsic amorphous semiconductor layer 152, and a p-type amorphous semiconductor layer 153 in this order.

The n-type amorphous semiconductor layer 151 consists of amorphous silicon doped with n-type impurities (for example, phosphorus). The film thickness of the n-type amorphous semiconductor layer 151 is about 50 nm.

The intrinsic amorphous semiconductor layer 152 consists of intrinsic amorphous silicon. The intrinsic amorphous semiconductor layer 152 is formed in contact with the n-type amorphous semiconductor layer 151. The film thickness of the intrinsic amorphous semiconductor layer is about 1.0 μm.

The p-type amorphous semiconductor layer 153 consists of amorphous silicon doped with p-type impurities (for example, boron). The p-type amorphous semiconductor layer 153 is formed in contact with the intrinsic amorphous semiconductor layer 152. The film thickness of the p-type amorphous semiconductor layer 153 is about 10 nm.

An upper electrode 16 is formed on the p-type amorphous semiconductor layer 153. The upper electrode 16 consists of, for example, Indium Tin Oxide (ITO), and the thickness thereof is about 100 nm.

Here, a diagram representing only the lower electrode 14, the photoelectric conversion layer 15, and the upper electrode 16 which are shown in FIG. 4A is shown in FIG. 4B. As illustrated in FIG. 4B, the end portions 14a and 14b of the lower electrode 14 in X-axis direction and the end portions 16a and 16b of the upper electrode 16 in X-axis direction are disposed on an inner side than the end portions 15a and 15b of the photoelectric conversion layer 15 in X-axis direction. Further, the end portions 16a and 16b of the upper electrode 16 are disposed on an inner side than the end portions 14a and 14b of the lower electrode 14. That is, the photodiode 12 in the present embodiment is formed such that the end portions of the photoelectric conversion layer 15 are disposed on an outer side than the end portions of the upper electrode 16 and the end portions of the lower electrode 14.

Returning to FIG. 4A, on the p-type amorphous semiconductor layer 153, an insulating film 17 (hereinafter, referred to as a protective film) is formed so as to cover the upper electrode 16. The protective film 17 is, for example, an inorganic insulating film consisting of silicon nitride (SiNx), and the film thickness thereof is about 50 nm.

On the second insulating film 104, a third insulating film 105 is formed so as to cover the protective film 17. The third insulating film 105 is, for example, an inorganic insulating film consisting of silicon nitride (SiNx), and the film thickness thereof is about 300 nm.

In the third insulating film 105 and the protective film 17, a contact hole CH2 is formed at a position overlapping the upper electrode 16.

On the third insulating film 105, a fourth insulating film 106 is formed on an outer side than the contact hole CH2. The fourth insulating film 106 consists of, for example, an organic transparent resin made of an acrylic resin or a siloxane-based resin, and has a film thickness of about 3.0 μm.

Bias wirings 18 are formed on the fourth insulating film 106. The bias wirings 18 are connected to the upper electrode 16 via the contact hole CH2, and are connected to the control unit 2 (refer to FIG. 1). The bias wirings 18 apply a bias voltage input from the control unit 2 to the upper electrode 16.

The bias wirings 18 have a stacked structure in which a first bias wiring layer 18a and a second bias wiring layer 18b are stacked. The first bias wiring layer 18a has a stacked structure in which, for example, a metal film consisting of titanium (Ti), a metal film consisting of aluminum (Al), and a metal film consisting of titanium (Ti) are stacked in this order. The film thicknesses of titanium (Ti) of the upper layer and the lower layer are about 50 nm, and the film thickness of aluminum (Al) is about 600 nm. The second bias wiring layer 18b consists of, for example, an ITO, and the thickness thereof is about 100 nm.

On the fourth insulating film 106, a fifth insulating film 107 is formed so as to cover the bias wirings 18. The fifth insulating film 107 is an inorganic insulating film consisting of silicon nitride (SiNx), and the film thickness thereof is about 200 nm.

A sixth insulating film 108 is formed on the fifth insulating film 107. The sixth insulating film 108 consists of, for example, an organic transparent resin made of an acrylic resin or a siloxane-based resin, and has a film thickness of about 3.0 μm.

(Method for Manufacturing Imaging Panel 1)

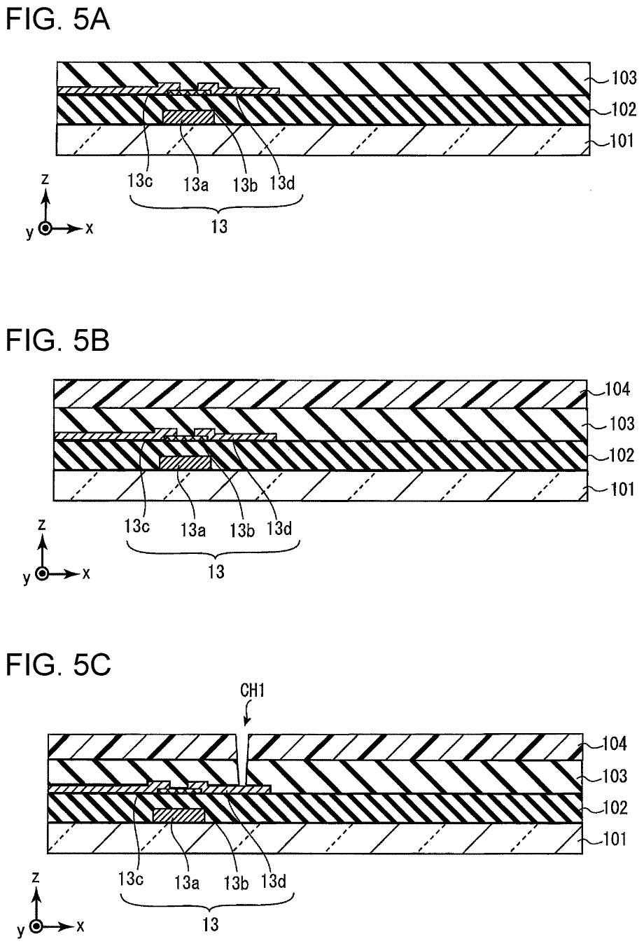

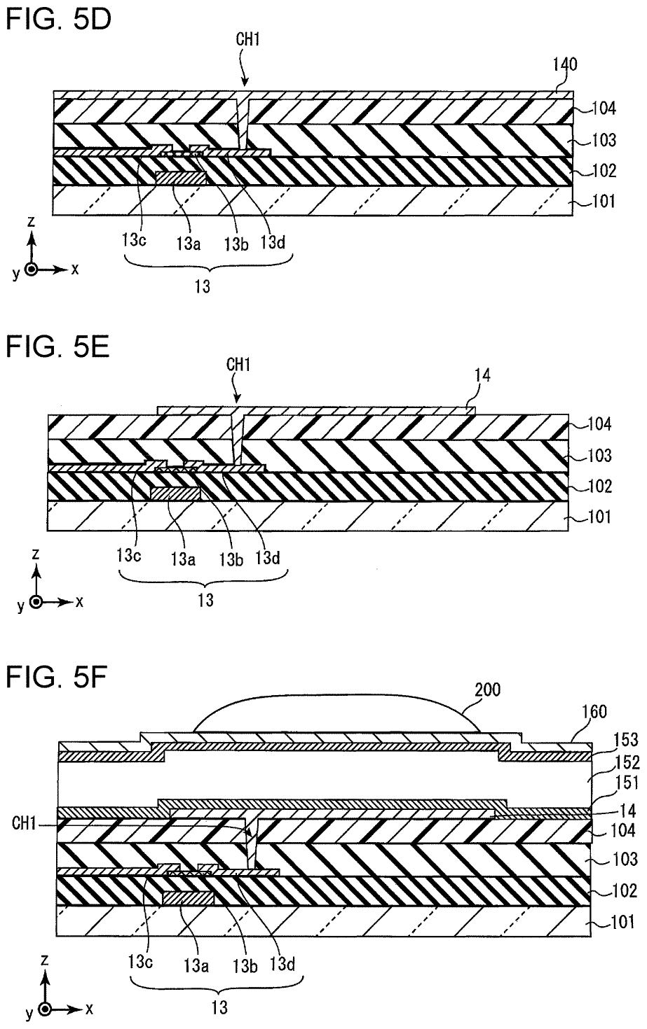

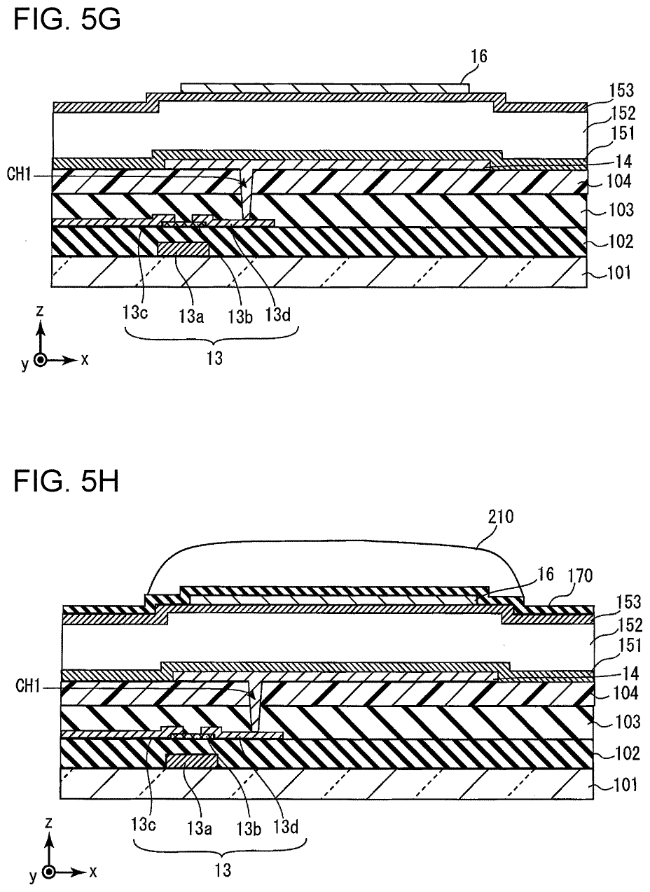

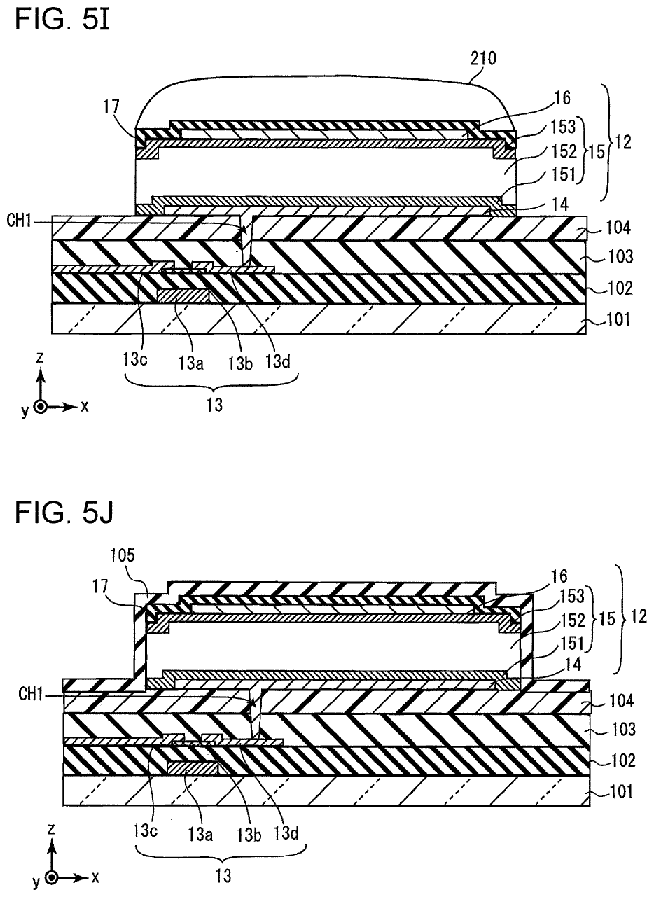

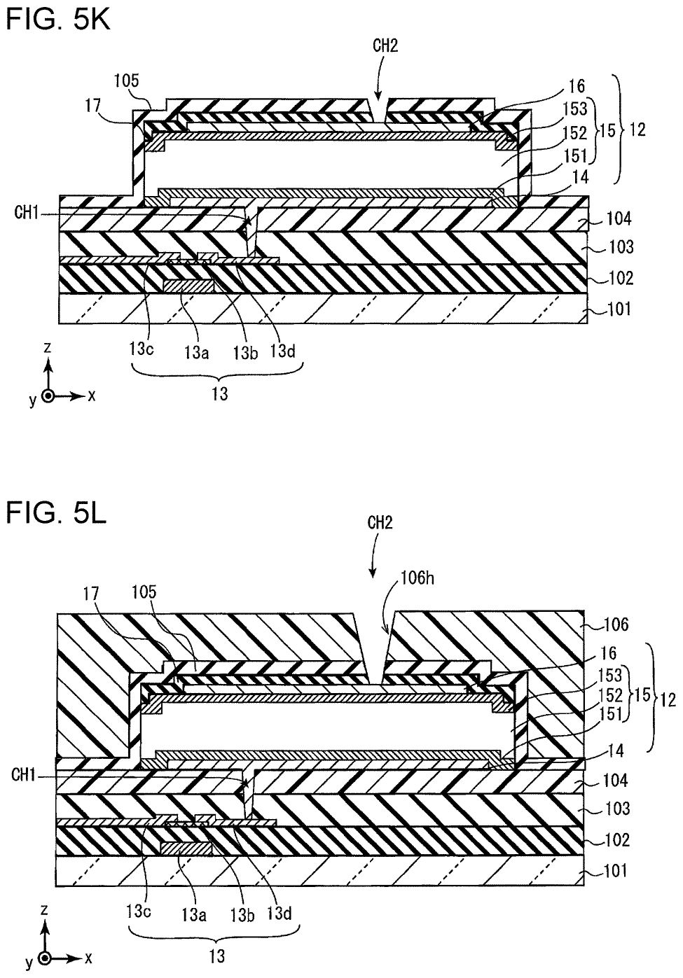

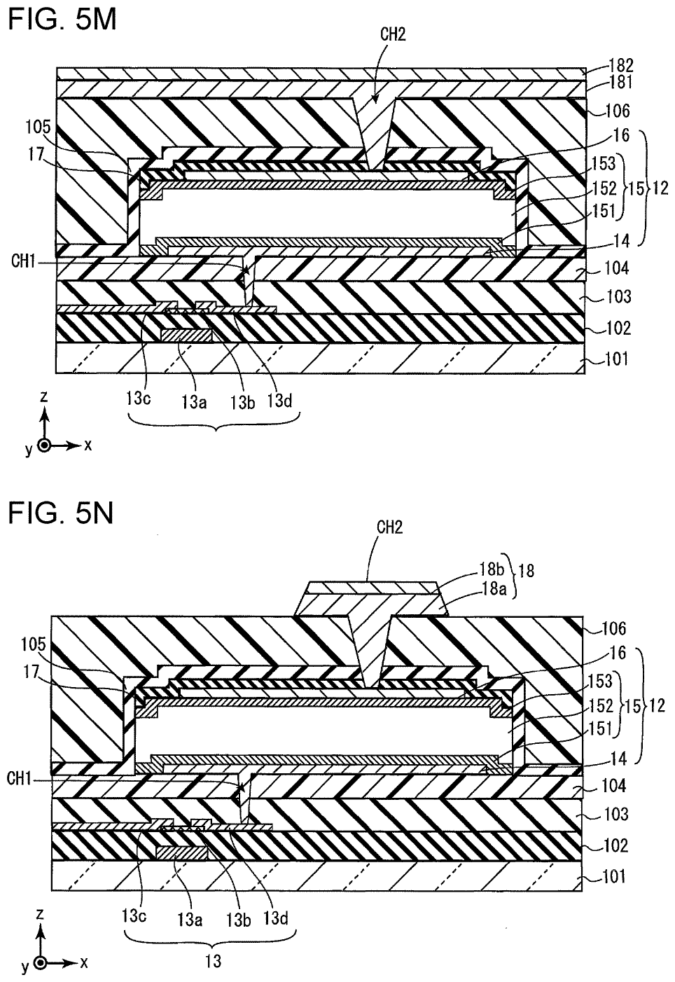

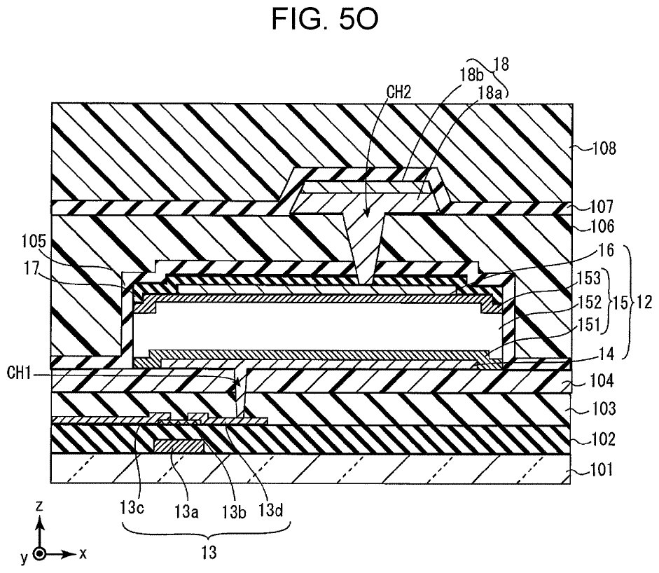

Next, a method for manufacturing the imaging panel 1 is described. FIGS. 5A to 5O are cross-sectional diagrams taken along line A-A (FIG. 3) of the pixel in each manufacturing step of the imaging panel 1.

As illustrated in FIG. 5A, on the substrate 101, the gate insulating film 102 and the TFT 13 are formed by known methods, and the first insulating film 103 consisting of silicon oxide (SiO²) is formed by a plasma CVD method to cover the TFT 13 (refer to FIG. 5A).

Then, for example, a second insulating film 104 consisting of silicon nitride (SiNx) is formed on the first insulating film 103 by using a plasma CVD method (refer to FIG. 5B).

Next, heat treatment of about 350° C. is applied to an entire surface of the substrate 101, a photolithography method and wet etching are performed to pattern the first insulating film 103 and the second insulating film 104, thereby forming the contact hole CH1 penetrating through the first insulating film 103 and the second insulating film 104 on the drain electrode 13d (refer to FIG. 5C).

Subsequently, a metal film 140 is formed on the second insulating film 104 in which titanium (Ti), aluminum (Al), and titanium (Ti) are stacked in this order by, for example, a sputtering method (refer to FIG. 5D).

Then, a photolithography method and wet etching are performed to pattern the metal film 140. By this, the lower electrode 14 connected to the drain electrode 13d via the contact hole CH1 is formed on the second insulating film 104 (refer to FIG. 5E).

Next, the n-type amorphous semiconductor layer 151, the intrinsic amorphous semiconductor layer 152, and the p-type amorphous semiconductor layer 153 are formed in this order on the second insulating film 104 to cover the lower electrode 14 by, for example, a plasma CVD method. Then, a transparent conductive film 160 consisting of ITO is formed on the p-type amorphous semiconductor layer 153, and a resist 200 is applied on the transparent conductive film 160 (refer to FIG. 5F). At this time, the resist 200 is formed such that end portions of the resist 200 in X-axis direction are disposed on an inner side than the end portions of the lower electrode 14 in X-axis direction.

Thereafter, a photolithography method and dry etching are performed to pattern the transparent conductive film 160. By this, the upper electrode 16 is formed on the p-type amorphous semiconductor layer 153 (refer to FIG. 5G). At this time, the end portions of the upper electrode 16 are disposed on an inner side than the end portions of the lower electrode 14.

Subsequently, an insulating film 170 consisting of silicon nitride (SiNx) is formed on the p-type amorphous semiconductor layer 153 so as to cover the upper electrode 16 by, for example, a plasma CVD method, and a resist 210 is applied on the insulating film 170 (refer to FIG. 5H). At this time, the resist 210 is formed such that the end portions of the resist 210 in X-axis direction are disposed on an outer side than the end portions of the lower electrode 14 in X-axis direction.

Then, a photolithography method and dry etching are performed to pattern the insulating film 170, the n-type amorphous semiconductor layer 151, the intrinsic amorphous semiconductor layer 152, and the p-type amorphous semiconductor layer 153. By this, the photoelectric conversion layer 15 and the protective film 17 are formed, and the photodiode 12 consisting of the lower electrode 14, the photoelectric conversion layer 15, and the upper electrode 16 is formed (refer to FIG. 5I). At this time, the end portions of the photoelectric conversion layer 15 and the end portions of the protective film 17 in X-axis direction are disposed on an outer side than the end portions of the lower electrode 14 and the end portions of the upper electrode 16 in X-axis direction. It is preferable that the end portions of the photoelectric conversion layer 15 in X-axis direction are separated by about 2.0 μm from the end portions of the upper electrode 16 in X-axis direction.

Subsequently, in order to suppress a leak current of the photoelectric conversion layer 15, a reduction treatment is performed on the surfaces of the protective film 17 and the photoelectric conversion layer 15 using hydrogen fluoride, in a state where the resist 210 is provided in FIG. 5I. At this time, since the upper electrode 16 is covered with the protective film 17, even if a reduction treatment is performed using hydrogen fluoride, the upper electrode 16 is not exposed to hydrogen fluoride. Therefore, by a reduction treatment using hydrogen fluoride, the metal ions in which the upper electrode 16 is dissolved do not adhere to the side surfaces of the photoelectric conversion layer 15.

Subsequently, the resist 210 is peeled off, and a third insulating film 105 consisting of silicon nitride (SiNx) is formed on the second insulating film 104 to cover the protective film 17 by, for example, a plasma CVD method (refer to FIG. 5J).

Then, a photolithography method and wet etching are performed to form the contact hole CH2 penetrating through the third insulating film 105 and the protective film 17 on the upper electrode 16 (refer to FIG. 5K).

Subsequently, a fourth insulating film 106 consisting of an acrylic resin or a siloxane-based resin is formed on the third insulating film 105 by, for example, a slit coating method. Then, an opening 106h of the fourth insulating film 106 is formed on the contact hole CH2 by a photolithography method (refer to FIG. 5L).

Next, a first bias wiring layer 181 in which titanium (Ti), aluminum (Al), and titanium (Ti) are stacked in this order is formed on the fourth insulating film 106 by, for example, a sputtering method. Thereafter, a second bias wiring layer 182 consisting of ITO is formed on the first bias wiring layer 181 (refer to FIG. 5M).

Then, a photolithography method and wet etching are performed to pattern the first bias wiring layer 181 and the second bias wiring layer 182. By this, bias wirings 18 (18a and 18b) connected to the upper electrode 16 via the contact hole CH2 are formed (refer to FIG. 5N).

Subsequently, a fifth insulating film 107 consisting of silicon nitride (SiN) is formed on the fourth insulating film 106 to cover the bias wirings 18 by, for example, a plasma CVD method. Thereafter, a sixth insulating film 108 consisting of an acrylic resin or a siloxane-based resin is formed on the fifth insulating film 107 by, for example, a slit coating method (refer to FIG. 5O). By this, the imaging panel 1 is formed.

The above is the method for manufacturing the imaging panel 1 in the present embodiment. As described above, the imaging panel 1 is formed such that the end portions of the lower electrode 14 are disposed on an inner side than the end portions of the photoelectric conversion layer 15. Further, the lower electrode 14 and the TFT 13 are connected to each other via the contact hole CH1 formed on the first insulating film 103 and the second insulating film 104 as the passivation film, in a region where the photoelectric conversion layer 15 is provided. Therefore, compared with the case where the end portions of the lower electrode 14 are disposed on an outer side than the end portions of the photoelectric conversion layer 15 and the lower electrode 14 and the TFT 13 are connected on an outer side than the end portions of the photoelectric conversion layer 15, a passivation film is not required to be provided between the photoelectric conversion layer 15 and the TFT 13, separately from the first insulating film 103 and the second insulating film 104, thereby the number of steps for forming the passivation film can be reduced.

Also, in the imaging panel 1, the end portions of the upper electrode 16 are disposed on an inner side than the end portions of the photoelectric conversion layer 15. In the above-described embodiment, the upper electrode 16 is formed in the step of FIG. 5E, and then, in the step of FIG. 5H, the insulating film 170 covering the upper electrode 16, the n-type amorphous semiconductor layer 151, the intrinsic amorphous semiconductor layer 152, and the p-type amorphous semiconductor layer 153 are etched using the same resist 210, therefore the metal ions of the upper electrode 16 do not adhere to the surface of the photoelectric conversion layer 15. Also, in the step on FIG. 5I, even if the photoelectric conversion layer 15 is formed and then a reduction treatment is performed on the surface of the photoelectric conversion layer 15 using hydrogen fluoride, the upper electrode 16 is not exposed to hydrogen fluoride thereby the metal ions of the upper electrode 16 do not adhere to the photoelectric conversion layer 15.

Accordingly, metal contamination does not occur on the side surfaces of the photoelectric conversion layer 15, and the leak current of the photoelectric conversion layer 15 can be suppressed.

Further, steps are generated at the end portions of the photoelectric conversion layer 15 by the influence of the lower electrode 14. Due to the effect of these steps, crystallinity of the p-type amorphous semiconductor layer 153 provided on the upper layer of the photoelectric conversion layer 15 becomes uneven, and charges may be trapped in the steps to increase the defect level. Therefore, by disposing the end portions of the upper electrode 16 on an inner side than the end portions of the lower electrode 14, it is possible that the upper electrode 16 is hardly affected by the steps generated in the photoelectric conversion layer 15 and the upper electrode and the photoelectric conversion layer 15 are surely connected to each other.

(Operation of X-Ray Imaging Device 100)

Here, an operation of the X-ray imaging device 100 shown in FIG. 1 will be described. First, X-rays are emitted from the X-ray source 3. At this time, the control unit 2 applies a predetermined voltage (bias voltage) to the bias wirings 18 (refer to FIG. 3 or the like). The X-rays emitted from the X-ray source 3 transmit through the object S to enter a scintillator 1A. The X-rays incident on the scintillator 1A are converted into fluorescence (scintillation light) and scintillation light is incident on the imaging panel 1. If scintillation light enters the photodiode 12 provided in each pixel on the imaging panel 1, scintillation light is changed to charges corresponding to the amount of scintillation light by the photodiode 12. A signal corresponding to the charges converted by the photodiode 12 are read out by a signal readout section 2B (refer to FIG. 2 or the like) through the source wiring 10 when the TFT 13 (refer to FIG. 2 or the like) is turned on by a gate voltage (positive voltage) output from the gate control section 2A through the gate wiring 11. Then, an X-ray image corresponding to the read signal is generated in the control unit 2.

Hereinabove, embodiments of the present invention are described, the above-described embodiments are merely examples for implementing the present invention. Accordingly, the present invention is not limited to the above-described embodiments, and the above-described embodiments can be appropriately modified and implemented without departing from the scope of the invention. Hereinafter, modifications of the present invention will be described.

(1) In the above-described embodiment, although the example in which the protective film 17 is provided on the photoelectric conversion layer 15 to cover the upper electrode 16 was described, the imaging panel 1 may have a configuration in which the protective film 17 is not provided. The upper electrode 16 is not exposed to hydrogen fluoride by the protective film 17 thereby the leak current of the photoelectric conversion layer 15 can be suppressed. However, even if the protective film 17 is not provided, a passivation film is not required to be provided between the photoelectric conversion layer 15 and the TFT 13 separately from the first insulating film 103 and the second insulating film 104, thereby the number of steps for forming the passivation film can be reduced.

(2) In the above-described embodiment, although an example in which not only the lower electrode 14 but also the end portions of the upper electrode 16 are disposed on an inner side than the end portions of the photoelectric conversion layer 15 was described, but at least the end portions of the lower electrode 14 may be disposed on an inner side than the end portions of the photoelectric conversion layer 15. For example, even in a case where the end portions of the upper electrode 16 are disposed at approximately the same position as the end portions of the photoelectric conversion layer 15, the passivation film is not required to be provided between the photoelectric conversion layer 15 and the TFT 13 separately from the first insulating film 103 and the second insulating film 104, since the end portions of the lower electrode 14 are disposed on an inner side than the end portions of the photoelectric conversion layer 15 thereby the number of steps for forming the passivation film can be reduced.

1. An imaging panel which generates an image based on scintillation light obtained from X-rays passing through an object, the imaging panel comprising:
a substrate;
a thin film transistor formed on the substrate;
a passivation film covering the thin film transistor;
a lower electrode provided on the passivation film and connected to the thin film transistor;
a photoelectric conversion layer provided on the passivation film and the lower electrode, and converting the scintillation light into a charge; and
an upper electrode provided on the photoelectric conversion layer,
wherein end portions of the lower electrode are disposed on an inner side than end portions of the photoelectric conversion layer, and
the lower electrode and the thin film transistor are connected to each other via a contact hole formed in the passivation film, in a region in which the photoelectric conversion layer is provided.

2. The imaging panel according to claim 1,
wherein end portions of the upper electrode are disposed on an inner side than the end portions of the lower electrode.

3. The imaging panel according to claim 1, further comprising:
a protective film covering the upper electrode, on the photoelectric conversion layer,
wherein end portions of the protective film are disposed on substantially the same position as the end portions of the photoelectric conversion layer.

4. A method for manufacturing an imaging panel which generates an image based on scintillation light obtained from X-rays passing through a subject, the method comprising:
a step of forming a thin film transistor on a substrate;
a step of forming a passivation film on the thin film transistor;
a step of forming a contact hole penetrating through the passivation film, on a drain electrode of the thin film transistor;
a step of forming a lower electrode connected to the drain electrode via the contact hole, on the passivation film;
a step of forming a first semiconductor layer having a first conductivity type, an intrinsic amorphous semiconductor layer, and a second semiconductor layer having a second conductivity type opposite to the first conductivity type in this order, on the passivation film and the lower electrode;
a step of forming an upper electrode on the second semiconductor layer; and
a step of forming a photoelectric conversion layer by etching the first semiconductor layer, the intrinsic amorphous semiconductor layer, and the second semiconductor layer,
wherein, in the step of forming the photoelectric conversion layer, the etching is performed such that end portions of the lower electrode are disposed on an inner side than end portions of the photoelectric conversion layer, and
the contact hole is formed on an inner side than the end portions of the photoelectric conversion layer.

5. The manufacturing method according to claim 4, further comprising:
a step of performing a reduction treatment using hydrogen fluoride on a surface of the photoelectric conversion layer after performing the etching such that end portions of the upper electrode are disposed on an inner side than the end portions of the photoelectric conversion layer in the step of forming the photoelectric conversion layer.

6. The manufacturing method according to claim 4, further comprising:
a step of forming a protective film covering the upper electrode, on the photoelectric conversion layer.
